(19) United States
(12) Patent Application Publication
(10) Pub. No.: US 2023/0194422 A1
(43) Pub. Date: Jun. 22, 2023

(54) CHEMICAL LIQUID SUPPLY UNIT, SUBSTRATE PROCESSING SYSTEM USING THE SAME, AND CHEMICAL LIQUID SUPPLY METHOD

(71) Applicant: SEMES CO., LTD., Cheonan-si (KR)

(72) Inventors: Seung Tae YANG, Yongin-si (KR); Sang Woo PARK, Daejeon (KR); Young Joon HAN, Cheonan-si (KR); Gi Hun CHOI, Changwon-si (KR); Moon Soon CHOI, Cheonan-si (KR); Seong Hyeon KIM, Cheonan-si (KR); Bu Young JUNG, Cheonan-si (KR)

(73) Assignee: SEMES CO., LTD., Cheonan-si (KR)

(21) Appl. No.: 18/080,552

(22) Filed: Dec. 13, 2022

(30) Foreign Application Priority Data
Dec. 16, 2021 (KR) 10-2021-0181000

(51) Int. Cl. G01N 21/3577; B01L 3/00

(52) U.S. Cl. CPC G01N 21/3577; B01L 3/502; G01N 2021/3595

(57) ABSTRACT

A chemical liquid supply unit includes a chemical liquid storage storing a chemical liquid, a chemical liquid supply line that is connected to the chemical liquid storage, the chemical liquid flowing through the chemical liquid supply line from the chemical liquid storage, and a chemical liquid inspection means detecting impurities from the chemical liquid flowing through the chemical liquid supply line using a spectroscopy method.

### CROSS REFERENCE TO RELATED APPLICATION

The present application claims priority to Korean Patent Application No. 10-2021-0181000, filed Dec. 16, 2021, the entire contents of which are incorporated by reference herein for all purposes.

### BACKGROUND OF THE INVENTION

### Field of the Invention

The present disclosure relates to a chemical liquid supply unit, a substrate processing system using the same, and a chemical liquid supply method. More particularly, the present disclosure relates to a technology capable of securing reliability and stability of process performance by detecting and removing impurities generated according to a chemical reaction when a chemical liquid is supplied through a chemical liquid supply unit.

### Description of the Related Art

Generally, various types of chemical liquids may be used in a semiconductor device manufacturing process and a flat panel display manufacturing process. For example, in a process of cleaning a substrate, various types of chemical liquids (for example, IPA) for cleaning the substrate may be used, and foreign substances and so on remaining on a surface of the substrate may be removed by processing the substrate with the chemical liquids.

When a chemical liquid is supplied to process a substrate, the supplied liquid may cause a chemical reaction and may be changed into unnecessary impurities due to various factors. Due to such impurities, a process yield is reduced, and a defective product is manufactured, and also there is a problem that risk of occurrence of a process accident increases.

Therefore, methods of identifying impurities by performing various inspections on a supplied chemical liquid have been proposed.

However, a chemical liquid inspection method according to such a conventional technology requires an excessive amount of time to analyze a chemical liquid, so that there is a problem that an immediate inspection cannot be performed practically while a process is performed.

### SUMMARY OF THE DISCLOSURE

Accordingly, the present disclosure has been made keeping in mind the above problems occurring in the related art, and an objective of the present disclosure is to provide a technology capable of inspecting impurities in real-time by performing a spectroscopy method and capable of performing an immediate action when the impurities are generated according to a chemical reaction when a chemical liquid is supplied, thereby solving a problem that the chemical liquid containing the impurities is introduced into a process processing.

The present disclosure is to monitor for occurrence of an IPA derivative such as acetone, the IPA derivative generated when IPA as a chemical liquid is supplied, thereby preventing an occurrence of a large number of defects due to the IPA derivative.

Furthermore, the present disclosure is to solve a problem that a chemical liquid supplied for a substrate processing causes a chemical reaction according to various factors and is changed into unnecessary impurities so that a process yield is reduced and a defective product is generated.

In addition, the present disclosure is to solve risk of an occurrence of a process accident due to impurities according to a chemical reaction of a chemical liquid.

In addition, the present disclosure is to solve a problem that an immediate inspection cannot be performed practically while performing a process since a conventional chemical liquid inspection method requires an excessive amount of time for analyzing a chemical liquid.

The objectives of the present disclosure are not limited thereto, and other objectives and other advantages of the present disclosure will be understood from the following description.

According to one aspect of the present disclosure, a chemical liquid supply unit includes a chemical liquid storage storing a chemical liquid, a chemical liquid supply line that is connected to the chemical liquid storage, the chemical liquid flowing through the chemical liquid supply line from the chemical liquid storage, and a chemical liquid inspection means detecting impurities from the chemical liquid flowing through the chemical liquid supply line using a spectroscopy method.

According to one aspect of the present disclosure, a substrate processing system includes a chemical liquid storage storing a chemical liquid, a chemical liquid supply line that is connected to the chemical liquid storage, wherein the chemical liquid flows through the chemical liquid supply line from the chemical liquid storage, a chemical liquid inspection means configured to detect using a spectroscopy method, wherein the impurities are generated during a time when the chemical liquid flows through the chemical liquid supply line, and a substrate processing apparatus connected to the chemical liquid supply line, and receiving the chemical liquid from the chemical liquid supply unit and cleaning a substrate using the chemical liquid. According to an aspect of the present disclosure, there is provided a chemical liquid supply method including: a chemical liquid supply process in which a chemical liquid stored in a chemical liquid storage unit is supplied to a chemical liquid supply line; an impurities detection process in which impurities generated according to a chemical reaction are detected by performing a spectroscopy method on the chemical liquid flowing through the chemical liquid supply line; and a chemical liquid supply determination process in which the chemical liquid is supplied to a substrate processing apparatus or the chemical liquid is discharged to an outside on the basis of an impurities detection result.

According to an aspect of the present disclosure, a chemical liquid supply unit includes a chemical liquid storage storing IPA as a chemical liquid, a chemical liquid supply line that is connected to the chemical liquid storage, wherein the chemical liquid flows through the chemical liquid supply line from the chemical liquid storage, a filter disposed in the chemical liquid supply line, a drain line connected to the chemical liquid supply line and configured to discharge the chemical liquid flowing through the chemical liquid supply line, a first valve disposed at a rear end of a connection portion of the drain line where the drain line is connected to the chemical liquid supply line, the first valve being configured to selectively open and close the chemical liquid supply line, a second valve disposed at the drain line, the second valve being configured to selectively open and close the drain line, a measurement probe inserted into the chemical liquid supply line, the measurement probe being configured to emit infrared light or near-infrared light to the chemical liquid flowing through the chemical liquid supply line and being configured to detect light transmitted through the chemical liquid or to detect light reflected on the chemical liquid, a Fourier transformer configured to acquire a spectrum from the light detected from the measurement probe, an analyzer configured to detect an IPA derivative on the basis of the spectrum, and a controller configured to control the first valve and the second valve on the basis of an analysis result of the analyzer.

According to the present disclosure as described above, real-time inspection may be performed by performing a spectroscopy method on impurities that are generated according to a chemical reaction when a chemical liquid is supplied, and an immediate action may be performed so that the chemical liquid containing the impurities is discharged to the outside, so that an effect of the impurities on a process may be eliminated.

Particularly, by detecting the occurrence of an IPA derivative generated when IPA as the chemical liquid is supplied, the occurrence of a large number of defects due to the impurities, such as acetone, acetic acid, isopropyl acetate, and so on may be prevented.

Furthermore, the present disclosure may solve the problem that a chemical liquid supplied for the substrate processing causes a chemical reaction according to various factors and is changed into unnecessary impurities so that the process yield is reduced and a defective product is generated, and the present disclosure may solve the risk of the occurrence of a process accident due to impurities according to the chemical reaction of the chemical liquid.

The effects of the present disclosure are not limited to those mentioned above, and other effects not mentioned will be clearly understood by those skilled in the art from the following description.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a view illustrating an embodiment of a substrate processing system in which the present disclosure is applied;

FIG. 2 is a view illustrating a configuration of an embodiment of a chemical liquid supply unit according to the present disclosure;

FIG. 3 is a view illustrating an embodiment of supplying a chemical liquid to a substrate processing apparatus through the chemical liquid supply unit according to the present disclosure;

FIG. 4A to 4C is a view illustrating a configuration of an embodiment of a chemical liquid inspection means of the chemical liquid supply unit according to the present disclosure;

FIG. 5 is a flowchart illustrating an embodiment of a chemical liquid supply method according to the present disclosure;

FIG. 6 is a flowchart illustrating an embodiment of a process of detecting and discharging an IPA derivative by using the chemical liquid supply method according to the present disclosure;

FIGS. 7a, 8a, 9a, and 10a show molecular structures of IPA, Acetone, Acetic Acid, and Isopropyl Acetate, respectively; and

FIGS. 7b, 8b, 9b, and 10b illustrate spectrums of IPA, Acetone, Acetic Acid, and Isopropyl Acetate, respectively.

### DETAILED DESCRIPTION OF THE INVENTION

Hereinafter, exemplary embodiments of the present disclosure will be described in detail with reference to the accompanying drawings, but the present disclosure is not limited or restricted to the embodiments.

Hereinafter, exemplary embodiments of the present disclosure will be described with reference to the accompanying drawings in order to describe the present disclosure, operational advantages of the present disclosure, and objectives achieved by embodiments of the present disclosure.

First, the terminology used herein is for the purpose of describing particular embodiments only and is not intended to be limiting. As used herein, the singular forms “a”, “an”, and “the” are intended to include the plural foils as well, unless the context clearly indicates otherwise. The terms “comprise”, “include”, “have”, and the like when used herein should be understood to specify the presence of stated features, numbers, steps, operations, elements, components, or combinations thereof but not to preclude the presence or addition of one or more other features, numbers, steps, operations, elements, components or combinations thereof.

In describing the present disclosure, when it is decided that a detailed description of a known configuration or function related to the disclosure makes the gist of the disclosure unclear, the detailed description is omitted.

The present disclosure proposes a technology capable of securing reliability and stability of process performance by detecting and removing impurities generated according to a chemical reaction when a chemical liquid is supplied through a chemical liquid supply unit.

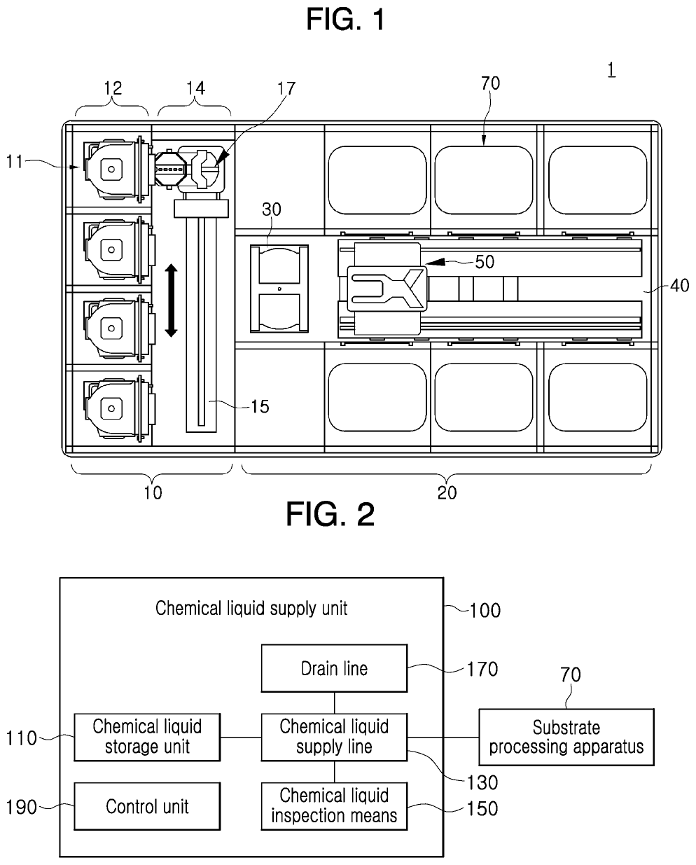

As illustrated in FIG. 1, a substrate processing system 1 in which the present disclosure is applied may include an index unit 10 and a process processing unit 20. The index unit 10 and the process processing unit 20 may be arranged in a row.

The index unit 10 may include a load port 12 and a transfer frame 14.

A carrier 11 in which a substrate W is stored may be seated in the load port 12. The load port 12 may include a plurality of load ports 12, and the plurality of load ports 12 may be arranged in a row. Furthermore, the number of load ports 12 may increase or decrease according to a process efficiency, a footprint condition, and so on of the substrate processing system 1.

A Front Opening Unified Pod (FOUP) may be used as the carrier 11. The carrier 11 may have a plurality of slots for receiving the substrates while the substrates are disposed in horizontal to the ground surface.

The transfer frame 14 may be disposed adjacent to the load port 12 and, preferably, the transfer frame 14 may be disposed between a buffer unit 30 of the process processing unit 20 and the load port 12. The transfer frame 14 may include an index rail 15 and an index robot 17. The index robot 17 may be seated on the index rail 15. The index robot 16 may transfer the substrate W between the buffer unit 30 and the carrier 11. The index robot 17 may linearly move along the index rail 15, or may rotate about an axis.

The process processing unit 20 may be arranged behind the substrate processing system 1 while being adjacent to the index unit 10.

The process processing unit 20 may include the buffer unit 30, a movement path 40, a main transfer robot 50, and a substrate processing apparatus 70.

The buffer unit 30 may be disposed in front of the process processing unit 20, and may be a place where the substrate W is temporarily stored and waits before the substrate W is returned between the substrate processing apparatus 70 and the carrier 11. The buffer unit 30 may be provided with a slot (not illustrated) in which the substrate is placed, and a plurality of slots (not illustrated) may be provided such that the plurality of slots is spaced apart from each other.

The movement path 40 may be disposed such that the movement path 40 corresponds to the buffer unit 30, and may provide a path through which the main transfer robot 50 moves. The substrate processing apparatuses 70 may be disposed on opposite sides of the movement path 40 such that the substrate processing apparatuses 70 are facing each other. The main transfer robot 50 moves through the movement path 40, and a movement rail along which the main transfer robot 50 is capable of being moved up and down to upper and lower levels of the substrate processing apparatus 70 and upper and lower levels of the buffer unit 30 may be mounted.

The main transfer robot 50 may be installed on the movement path 40, and may transfer the substrate W between the substrate processing apparatus 70 and the buffer unit 30 or between each substrate processing apparatus 70. The main transfer robot 50 may linearly move along the movement path 40, or may rotate about an axis.

A plurality of substrate processing apparatuses 70 may be provided, and may be disposed on the opposite sides of the movement path 40. Some of the substrate processing apparatuses 70 may be disposed along a lengthwise direction of the movement path 40, and some of the substrate processing apparatuses 70 may be disposed such that some of the substrate processing apparatuses 70 are stacked with each other. The placement position of the substrate processing apparatuses 70 and the number of the substrate processing apparatuses 70 may increase or decrease. As an example, the substrate processing apparatus 70 may be provided only on one side of the movement path 40. In addition, the substrate processing apparatus 70 may be provided on one side or opposite sides of the movement path 40 in a single layer.

The substrate processing apparatus 70 may perform a cleaning process on the substrate W. The substrate processing apparatuses 70 may have different structures according to the types of the cleaning process, or each of the substrate processing apparatuses 70 may have the same structure. Furthermore, optionally, the substrate processing apparatuses 70 may be divided into a plurality of groups such that the structures of the substrate processing apparatuses 70 pertaining to the same group are the same and the structures of the substrate processing apparatus 70 pertaining to different groups are different. The substrate processing apparatuses 70 may be distinguished from each other according to the types of chemicals used and the types of cleaning methods. Alternatively, the substrate processing apparatus 70 may be provided such that the substrate processing apparatus 70 sequentially performs processes on one substrate W for each group.

In addition, the substrate processing system 1 may include a chemical liquid supply unit (not illustrated) that supplies a chemical liquid corresponding to a corresponding processing process to the substrate processing apparatus 70.

In the present disclosure, there is provided a substrate processing system 1 which is capable of detecting impurities that can be generated according to a chemical reaction when a chemical liquid is supplied and which is capable of discharging a chemical liquid containing impurities to the outside by applying the chemical liquid supply unit that will be described hereinafter, thereby being capable of eliminating the effect of impurities on a process.

The present disclosure proposes the chemical liquid supply unit that supplies the chemical liquid to each substrate processing apparatus 70 which is provided in the substrate processing system 1 that is described above.

FIG. 2 is a view illustrating a configuration of an embodiment of a chemical liquid supply unit according to the present disclosure.

A chemical liquid supply unit 100 may provide a chemical liquid to the substrate processing apparatus 70.

The chemical liquid supply unit 100 may include a chemical liquid storage unit 110, a chemical liquid supply line 130, a chemical liquid inspection means 150, a drain line 170, a controller 190, and so on.

The chemical liquid storage unit 110 may store various chemical liquids that will be used in a substrate processing process, and may supply stored chemical liquids to the substrate processing apparatus 70 when the stored chemical liquids are required to be provided. The chemical liquid storage unit 110 may receive a chemical liquid through a chemical liquid inlet line (not illustrate) and may temporarily store the chemical liquid.

The chemical liquid supply line 130 may supply the chemical liquid stored in the chemical liquid storage unit 110 to the substrate processing apparatus 70. The chemical liquid supply line 130 may provide a path through which a chemical liquid flows. In order to adjust a chemical liquid according to a process processing condition, various components such as a valve, a heater, a pump, a flow meter, a filter, and so on are disposed on the chemical liquid supply line 130, so that the supply amount, the density, the temperature of the chemical liquid may be adjusted and impurities may be removed.

As an example, the chemical liquid storage unit 110 may receive and store isopropyl alcohol (IPA) as an organic solvent for the substrate processing process, and the chemical liquid supply line 130 may supply IPA to the substrate processing apparatus 70.

The number and the shape of the chemical liquid storage unit 110 and the chemical liquid supply line 130 may be changed in consideration of the types of the supplied chemical liquid according to the substrate processing process.

The chemical liquid inspection means 150 may detect impurities contained in a chemical liquid that flows through the chemical liquid supply line 130. In an embodiment, the chemical liquid inspection means 150 may perform a spectroscopic examination on the chemical liquid flowing through the chemical liquid supply line 130 in real time, thereby inspecting impurities generated according to a chemical reaction.

As an example, when IPA is supplied through the chemical liquid supply line 130, an IPA derivative may be generated. Accordingly, due to such an unnecessary IPA derivative, defect in a product may occur during processing a process. In the present disclosure, by using a Fourier-transform infrared spectrometer (FT-IR) or a Fourier-transform near infrared spectrometer (FT-NIR), a spectrum of a chemical liquid flows through the chemical liquid supply line 130 may be acquired, and whether an IPA derivative is contained or not may be determined by checking whether a peak of a wavenumber corresponding to the IPA derivative exists in the spectrum.

The drain line 170 may be connected to a middle portion of chemical liquid supply line 130, so that the drain line 170 may discharge a chemical liquid that flows through the chemical liquid supply line 130 to the outside.

The controller 190 may selectively control the supply of a chemical liquid through the chemical liquid supply line 130 to the substrate processing apparatus 70. On the basis of an inspection result from the chemical liquid inspection means 150, the controller 190 may stop the supply of a chemical liquid through the chemical liquid supply line 130 to the substrate processing apparatus 70, and may discharge the chemical liquid to the outside through the drain line 170.

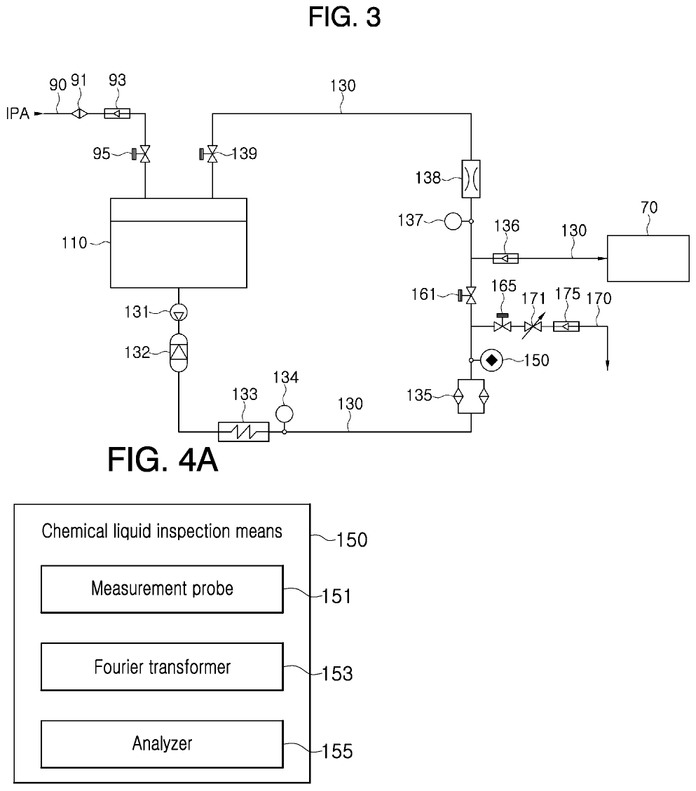

FIG. 3 is a view illustrating an embodiment of supplying a chemical liquid to the substrate processing apparatus through the chemical liquid supply unit according to the present disclosure.

In FIG. 3, an example in which the chemical liquid supply unit 100 supplies IPA to the substrate processing apparatus 70.

Generally, a cleaning process may include a chemical processing process of removing foreign substances on the substrate by supplying a chemical liquid on the substrate, a rinse processing process of removing the chemical liquid remaining on the substrate by supplying pure water on the substrate, a dry processing process of removing the pure water remaining on the substrate, and so on.

A supercritical fluid may be used for the dry processing of the substrate. As an example, after the pure water on the substrate is substituted with an organic solvent, the organic solvent left on the substrate is dissolved in the supercritical fluid by supplying the supercritical fluid to an upper surface of the substrate within a high-pressure chamber of the substrate processing apparatus 70, thereby being capable of removing the organic solvent from the substrate. At this time, IPA may be used as the organic solvent, and carbon dioxide (CO₂), which has a relatively low critical temperature and a relatively low critical pressure and in which IPA is dissolved well, may be used as the supercritical fluid.

The chemical liquid storage unit 110 is a storage tank in which a chemical liquid is temporarily stored, and may receive and store IPA from an IPA source through a source line 90. On the source line 90, a filter 91, a flow meter 93, a valve 95, and so on may be disposed, so that the supply of IPA may be controlled.

IPA stored in the chemical liquid storage unit 110 may be provided to the substrate processing apparatus 70 through the chemical liquid supply line 130.

On the chemical liquid supply line 130, a pump 131, a damper 132, a heater 133, a thermometer 134, a filter 135, a flow meter 137, and so on may be disposed, so that a temperature, a flow rate, and so on of IPA supplied to the substrate processing apparatus 70 may be controlled.

In addition, on the chemical liquid supply line 130, a pressure gauge 138, a flow rate control valve (constant pressure valve) 139, and so on may be disposed, so that a pressure of IPA supplied through the chemical liquid supply line 130 may be controlled. The chemical liquid supply line 130 may supply IPA to the substrate processing apparatus 70 between the filter 135 and the flow rate control valve 139. A first valve 161 that controls the supply of IPA by selectively opening and closing the chemical liquid supply line 130 may be disposed on a front end portion of the chemical liquid supply line 130, the front end portion being connected to the substrate processing apparatus 70.

Furthermore, the chemical liquid supply line 130 may include a circulation line, and an end of the circulation line is connected to the chemical liquid storage unit 110 and the flow rate control valve 139 is disposed on a front end portion of the circulation line, so that a chemical liquid that is not supplied to the substrate processing apparatus 70 may be collected to the chemical liquid storage unit 110.

The chemical liquid inspection means 150 may be disposed on the chemical liquid supply line 130. In an embodiment, a measurement probe of the chemical liquid inspection means 150 may be disposed in the chemical liquid supply line 130. For example, the chemical liquid supply line 130 may have an inspection port through which the measurement probe may be inserted into the chemical liquid supply line

The measurement probe of the chemical liquid inspection means 150 may be disposed at an appropriate position on the chemical liquid supply line 130. Preferably, the measurement probe of the chemical liquid inspection means 150 may be disposed between the flow rate control valve 139 and the filter 135 disposed on the chemical liquid supply line 130. The reason for this arrangement is that impurities such as acetone induced in the filter 135 is relatively largely contained in IPA after IPA has passed through the filter 135.

By using the measurement probe, the chemical liquid inspection means 150 may perform an inspection on IPA that flows through the chemical liquid supply line 130, and may determine whether an IPA derivative is contained or not.

The drain line 170 may be connected to a front end of the first valve 161 on the chemical liquid supply line 130.

The drain line 170 may discharge IPA that flows through the chemical liquid supply line 130 to the outside. A second valve 165 that selectively opens and closes the drain line 170, a needle valve 171 that precisely controls a discharge flow rate, and a flow meter 175 that measures the discharge flow rate may be disposed on the drain line 170.

A controller (not illustrated) controls the first valve 161 and the second valve 165 on the basis of an inspection result of the chemical liquid inspection means 150, so that the controller may supply IPA to the substrate processing apparatus 70 or may discharge IPA through the drain line 170.

By using the chemical liquid supply unit 100 according to the present disclosure, a content of an IPA derivative may be inspected in real-time when IPA is supplied, and IPA that flows through the chemical liquid supply line 130 may be immediately discharged through the drain line 170 when IPA contains the IPA derivative, so that defect generated due to the supply of IPA containing an IPA derivative during process processing may be removed.

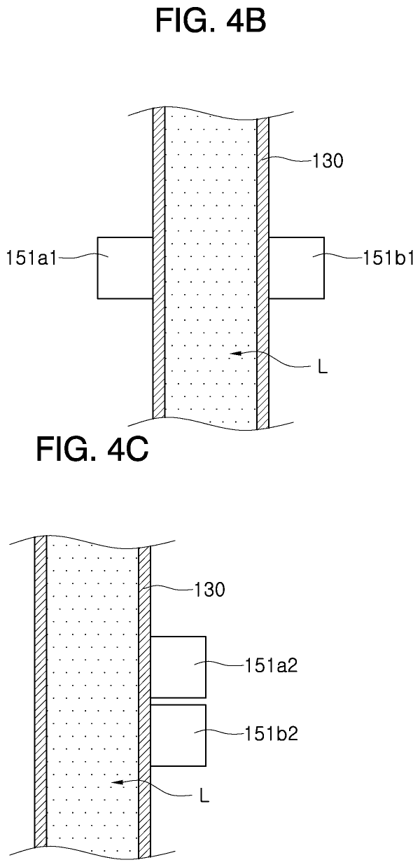

In the present disclosure, the chemical liquid inspection means 150 may identify impurities contained in a chemical liquid by using a Fourier-transform infrared spectrometer (FT-IR). Furthermore, in relation to the chemical liquid inspection means 150, FIG. 4A illustrates a configuration of an embodiment the chemical liquid inspection means of the chemical liquid supply unit according to the present disclosure.

The chemical liquid inspection means 150 may include a Fourier-transform infrared spectrometer (FT-IR) or a Fourier-transform near infrared spectrometer (FT-NIR). As an example, Fourier-transform infrared spectroscopy is a type of infrared spectroscopy that uses white light in infrared range in which phase has been modulated by an interferometer. Furthermore, in the Fourier-transform infrared spectroscopy, infrared light is emitted onto a sample, and an energy absorption corresponding to the vibration and rotation of a molecule under dipole moment change is measured.

The chemical liquid inspection means 150 may include a measurement probe 151, a Fourier transformer 153, an analyzer 155, and so on.

The measurement probe 151 may be disposed on the chemical liquid supply line 130, and may emit infrared light or near-infrared light to a chemical liquid that flows through the chemical liquid supply line 130, and the measurement probe 151 may detect light transmitted through the chemical liquid or reflected on the chemical liquid.

As an example, the measurement probe 151 including a light emitting part 151a1, 151a2 and a light receiving part 151b1, 151b2 disposed on the chemical liquid supply line 130 may detect light transmitted through the chemical liquid L in FIG. 4B or reflected on the chemical liquid L in FIG. 4C.

The Fourier transformer 153 may acquire a spectrum from the light detected from the measurement probe 151. That is, the Fourier transformer 153 transforms the detected light into a frequency domain through a Fourier transform, so that a spectrum of an energy absorption distribution of a chemical liquid to infrared light or near-infrared light may be acquired.

In addition, impurities of a chemical liquid may be determined on the basis of the acquired spectrum.

When radiant light passes through a solid, liquid, or gas layer, and electrons composing an atom, a molecule, or an ion absorb the radiant light, the electrons are transferred to an energy level corresponding to a photon energy of the radiant light. The difference between the electron energy levels is inherent to each chemical species. Therefore, the species composing a target material can be analyzed by inspecting a frequency of the absorbed radiant light. The frequency may be expressed by a propagation speed v and a wavelength λ, and a spectrum may be expressed by a wavenumber that is a reciprocal of the wavelength.

The analyzer 155 may identify the corresponding material by using a peak existing at a specific wavenumber in a spectrum.

As an example, when IPA is supplied as a chemical liquid, whether an IPA derivative is contained in IPA that flows through the chemical liquid supply line 130 or not may be identified by using a spectrum. Furthermore, a major IPA derivative has a double bond of C and O. In this situation, in a spectrum, a peak may appear in a wavenumber range of 1700 cm⁻¹ to 1730 cm⁻¹. More precisely, the peak appears near 1715 cm⁻¹ of a wavenumber.

By using this, the analyzer 155 may determine whether the major IPA derivative is contained or not.

In the present disclosure, by using the chemical liquid inspection means described above, whether impurities are contained or not may be identified in real-time while a chemical liquid is supplied.

In the present disclosure, a chemical liquid supply method performed through the above-described chemical liquid supply unit according to the present disclosure is proposed. Hereinafter, the chemical liquid supply method according to the present disclosure will be described through an embodiment. The chemical liquid supply method according to the present disclosure is realized through the above-described chemical liquid supply unit according to the present disclosure, so that reference will be also made to an embodiment of the chemical liquid supply unit.

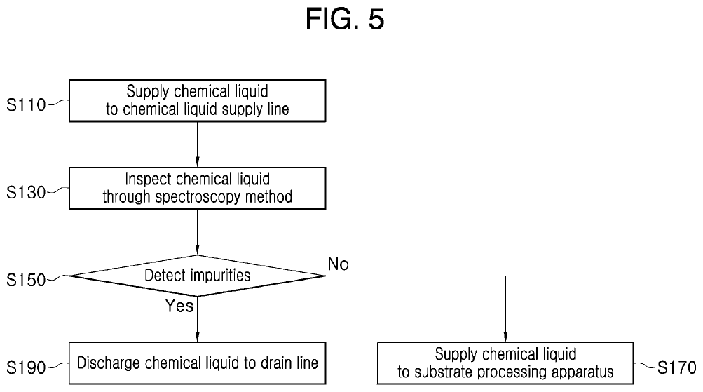

FIG. 5 is a flowchart illustrating an embodiment of a chemical liquid supply method according to the present disclosure.

While a chemical liquid stored in the chemical liquid storage unit 110 is supplied through the chemical liquid supply line 130 (S110), an inspection on a chemical liquid flowing through the chemical liquid supply line 130 may be performed by applying a spectroscopy method through the chemical liquid inspection means 150 (S130).

The chemical liquid inspection means 150 determines whether impurities are contained or not on the basis of an inspection result. Furthermore, in the inspection result of the chemical liquid inspection means 150, when there are no impurities or a content of impurities is below a reference value, the controller 190 may supply the chemical liquid to the substrate processing apparatus 70 through the chemical liquid supply line 130 (S170).

In the inspection result of the chemical liquid inspection means 150, when impurities exist or the content of impurities is above the reference value, the controller 190 may discharge the supplied chemical liquid to the drain line 170 through the chemical liquid supply line

The discharge of the chemical liquid through the drain line 170 may be performed for a set time or a set flow rate. Furthermore, the controller 190 may perform the process described above again, and may determine whether to supply the chemical liquid to the substrate processing apparatus 70 through the chemical liquid supply line 130 or to discharge the chemical liquid through the drain line 170.

The chemical liquid supply method according to the present disclosure will be described in more detail by applying the method to the supply of IPA.

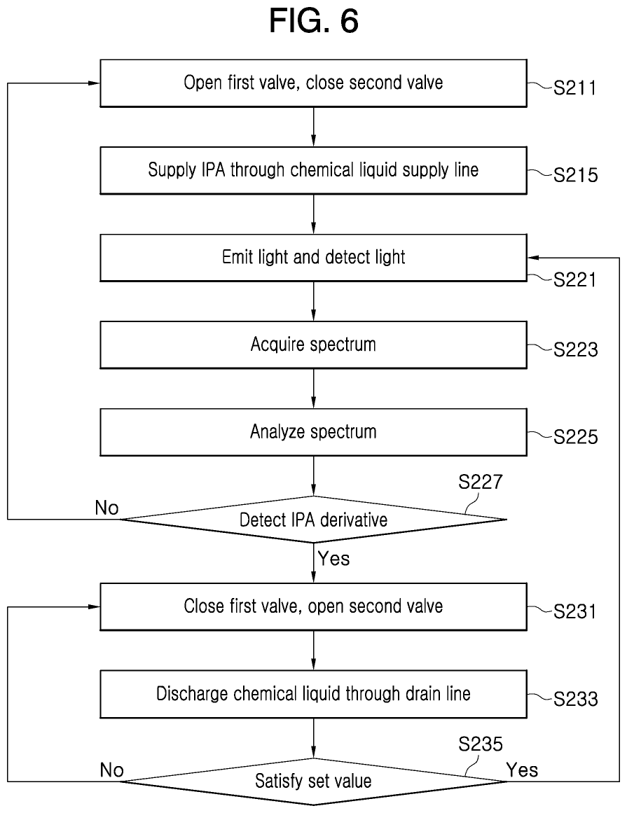

FIG. 6 is a flowchart illustrating an embodiment of a process of detecting and discharging an IPA derivative by using the chemical liquid supply method according to the present disclosure.

In describing this embodiment, reference will be made to the embodiment in FIG. 3 in which IPA is supplied through the chemical liquid supply unit that is described above.

The controller 190 supplies IPA stored in the chemical liquid storage unit 110 to the chemical liquid supply line 130. At this time, in order to IPA flowing to the chemical liquid supply line 130 to not be discharged to the drain line 170, the controller 190 opens the first valve 161 of the chemical liquid supply line 130 and closes the second valve 165 of the drain line 170 (S211).

While IPA is supplied through the chemical liquid supply line 130 (S215), infrared light or near-infrared light is emitted to the chemical liquid flowing through the chemical liquid supply line 130 and transmitted light or reflected light is detected by using the measurement probe 151 of the chemical liquid inspection means 150 (S221).

The Fourier transformer 153 of the chemical liquid inspection means 150 transforms the detected light into a frequency domain through a Fourier transform, and a spectrum of energy absorption distribution of the chemical liquid to infrared light or near-infrared light is acquired (S223).

Then, the analyzer 155 of the chemical liquid inspection means 150 analyzes the spectrum by identifying a wavenumber at which a peak exists on the acquired spectrum (S225). The analyzer 155 may determine whether an IPA derivative is contained or not by using an analysis result.

The major IPA derivative has a double bond of C and O, and the double bond of C and O is expressed as a peak at a wavenumber range of 1700 cm⁻¹ to 1730 cm⁻¹ on the spectrum. More precisely, the peak appears near a wavenumber of 1715 cm⁻¹.

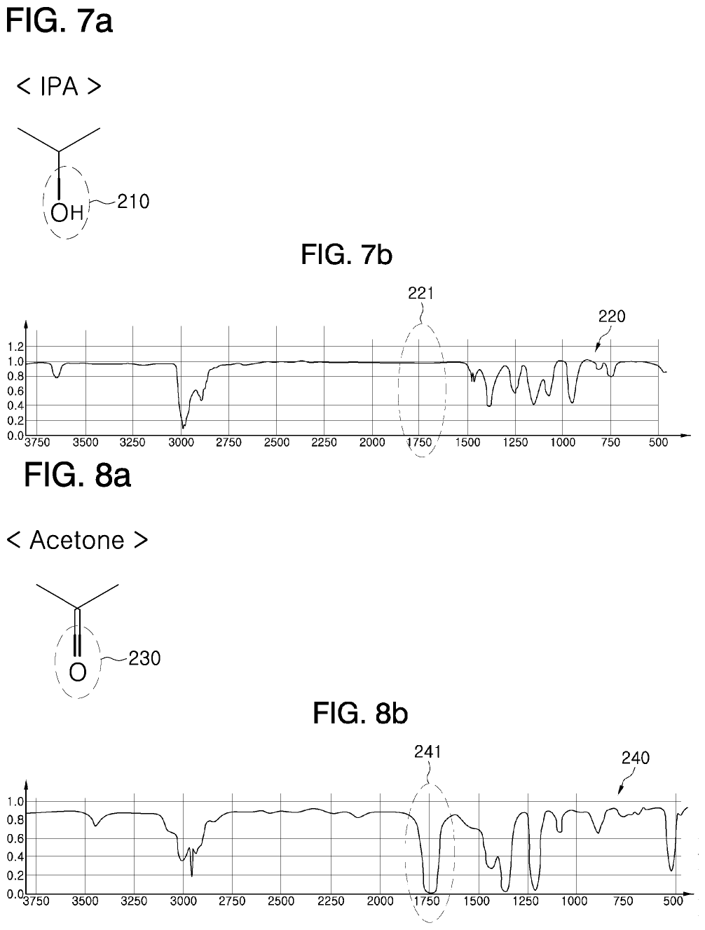

As an example, FIG. 7 illustrates a spectrum of IPA that does not contain an IPA derivative.

The molecular structure of IPA has a single bond 210 between an OH group and C, so that there is no peak in a wavenumber range 221 of 1700 cm⁻¹ to 1730 cm⁻¹ on the spectrum 220.

FIG. 8 illustrates a spectrum of IPA in which acetone is contained.

The molecular structure of acetone has a double bond 230 between O and C, so that a peak appears in a wavenumber range 241 of 1730 cm⁻¹ to 1700 cm⁻¹ on a spectrum 240.

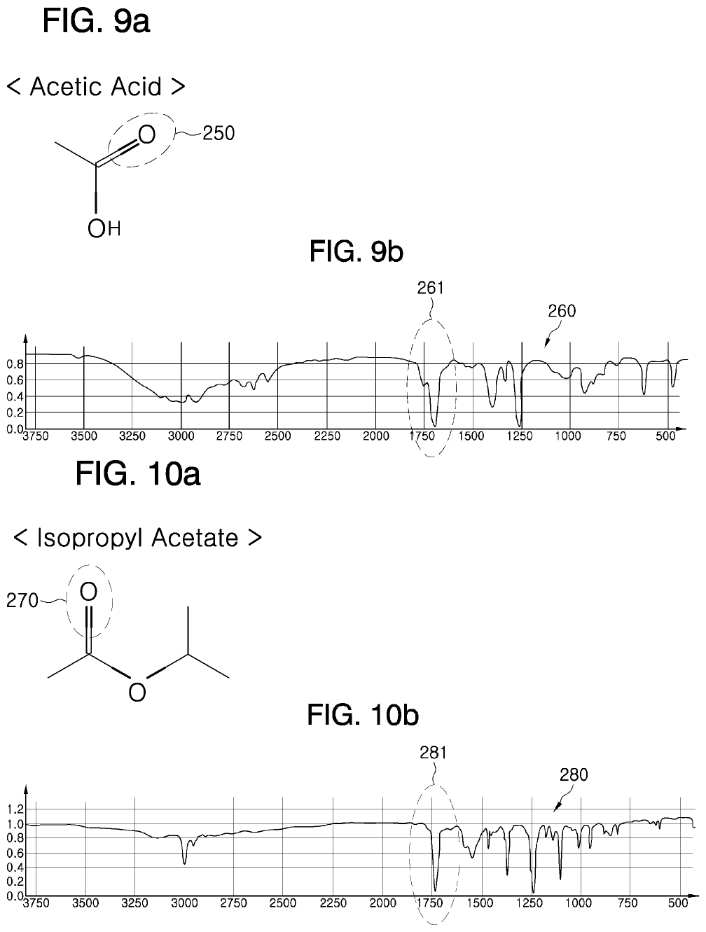

FIG. 9 illustrates a spectrum of IPA in which acetic acid is contained.

The molecular structure of acetic acid has a single bond between an OH group and C, but O and C connected thereto have a double bond 250, so that a peak appears near 1710 cm⁻¹ of a wavenumber 261 on a spectrum 260.

FIG. 10 illustrates a spectrum of IPA in which isopropyl acetate is contained.

The molecular structure of isopropyl acetate has a double bond 270 between O and C, so that a peak appears near 1720 cm⁻¹ of a wavenumber 281 on a spectrum 280.

As such, the major IPA derivative may be identified by analyzing a spectrum.

In the analysis result of the chemical liquid inspection means 150, when the IPA derivative is not detected or the content of the IPA derivative is insignificant below the set value, the controller 190 maintains the first valve 161 of the chemical liquid supply line 130 to be opened and maintains the second valve 165 of the drain line 170 to be closed, so that IPA is continuously supplied to the substrate processing apparatus 70 through the chemical liquid supply line 130.

On the contrary, in the analysis result of the chemical liquid inspection means 150, when the IPA derivative is detected, the controller 190 closes the first valve 161 of the chemical liquid supply line 130 and opens the second valve 165 of the drain line 170 (S231), so that the supply of IPA to the substrate processing apparatus 70 through the chemical liquid supply line 130 is stopped and IPA flowing through the chemical liquid supply line 130 is discharged to the drain line 170 (S233).

The controller 190 performs the discharge of IPA through the drain line 170 for a set time or a set flow rate, and determines whether the discharge of IPA reaches the set time or the set flow rate (S235).

When the discharge of IPA reaches the set time or the set flow rate, the controller 190 inspects again whether the IPA derivative is contained in IPA flowing through the chemical liquid supply line 130 by using the chemical liquid inspection means 150, and may repeatedly perform the processes according to the inspection result.

According to the present disclosure as described above, a real-time inspection may be performed by performing a spectroscopy method on impurities that are generated according to a chemical reaction when a chemical liquid is supplied, and an immediate action may be performed so that the chemical liquid containing the impurities is discharged to the outside, so that an effect of the impurities on a process may be eliminated.

Particularly, by detecting the occurrence of the IPA derivative generated when IPA as the chemical liquid is supplied, the occurrence of a large number of defects due to the impurities such as acetone, acetic acid, isopropyl acetate, and so on may be prevented.

Furthermore, the present disclosure may solve the problem that the chemical liquid supplied for the substrate processing causes the chemical reaction according to various factors and is changed into unnecessary impurities so that the process yield is reduced and the defective product is generated, and the present disclosure may solve the risk of the occurrence of the process accident due to impurities according to the chemical reaction of the chemical liquid.

Although the embodiments of the present disclosure have been disclosed for illustrative purposes, those skilled in the art will appreciate that various modifications, additions, and substitutions are possible, without departing from the scope and spirit of the present disclosure. Accordingly, embodiments disclosed in the present disclosure are provided for describing the present disclosure and are not intended to limit the technical ideas of the present disclosure. The technical ideas of the present disclosure are not limited to the embodiments. The scope of the present disclosure should be construed as being covered by the scope of the appended claims, and all technical ideas falling within the scope of the claims should be construed as being included in the scope of the present disclosure.

What is claimed is:

1. A substrate processing system comprising:
a chemical liquid supply unit comprising:
a chemical liquid storage storing a chemical liquid;
a chemical liquid supply line that is connected to the chemical liquid storage, wherein the chemical liquid flows through the chemical liquid supply line from the chemical liquid storage; and
a chemical liquid inspection means configured to detect impurities from the chemical liquid flowing through the chemical liquid supply line using a spectroscopy method,
wherein the impurities are generated during a time when the chemical liquid flows through the chemical liquid supply line.

2. The substrate processing system of claim 1, wherein the chemical liquid inspection means comprises a Fourier-transform infrared spectrometer (FT-IR) or a Fourier-transform near-infrared spectrometer (FT-NIR).

3. The substrate processing system of claim 1,
wherein the chemical liquid storage is configured to store isopropyl alcohol (IPA), and
wherein the IPA stored in the chemical liquid storage is supplied through the chemical liquid supply line.

4. The substrate processing system of claim 3,
wherein the impurities include an IPA derivative.

5. The substrate processing system of claim 4,
wherein the chemical liquid inspection means is configured to detect the IPA derivative on the basis of an existence of a peak of a wavenumber on a spectrum.

6. The substrate processing system of claim 1,
wherein the chemical liquid inspection means comprises:
a measurement probe disposed on the chemical liquid supply line, the measurement probe being configured to emit infrared light or near-infrared light to the chemical liquid flowing through the chemical liquid supply line and being configured to detect light transmitted through the chemical liquid or reflected on the chemical liquid;
a Fourier transformer configured to acquire a spectrum from the light detected from the measurement probe; and
an analyzer configured to determine impurities on the basis of the spectrum.

7. The substrate processing system of claim 6, further comprising:
a filter disposed in the chemical liquid supply line,
wherein the measurement probe is disposed at a rear end of the filter in light of a flowing direction of the chemical liquid.

8. The substrate processing system of claim 1, further comprising:
a drain line connected to the chemical liquid supply line and configured to discharge the chemical liquid flowing through the chemical liquid supply line.

9. The substrate processing system of claim 8, further comprising:
a first valve disposed at a rear end of a connection portion of the drain line where the drain line is connected to the chemical liquid supply line, the first valve being configured to selectively open and close the chemical liquid supply line;
a second valve disposed at the drain line, the second valve being configured to selectively open and close the drain line; and
a controller configured to control the first valve and the second valve.

10. The substrate processing system of claim 9,
wherein the controller is configured to selectively control the first valve and the second valve on the basis of an inspection result of the chemical liquid inspection means.

11. The substrate processing system of claim 1, further comprising:
a substrate processing apparatus connected to the chemical liquid supply line and configured to receive the chemical liquid from the chemical liquid supply unit and to clean a substrate using the chemical liquid.

12. A chemical liquid supply method comprising:
a chemical liquid supply process in which a chemical liquid stored in a chemical liquid storage unit is supplied to a chemical liquid supply line;
an impurities detection process in which impurities generated according to a chemical reaction are detected by performing a spectroscopy method on the chemical liquid flowing through the chemical liquid supply line; and
a chemical liquid supply determination process in which the chemical liquid is supplied to a substrate processing apparatus or the chemical liquid is discharged to an outside on the basis of an impurities detection result.

13. The chemical liquid supply method of claim 12, wherein, in the impurities detection process, the impurities on the chemical liquid supply line are detected by using a Fourier-transform infrared spectrometer (FT-IR) or a Fourier-transform near-infrared spectrometer (FT-NIR).

14. The chemical liquid supply method of claim 12, wherein IPA stored in the chemical liquid storage unit is supplied to the chemical liquid supply line in the chemical liquid supply process, and an IPA derivative on the chemical liquid supply line is detected in the impurities detection process.

15. The chemical liquid supply method of claim 14, wherein, in the impurities detection process, the IPA derivative is detected on the basis of an existence of a peak of a wavenumber on a spectrum.

16. The chemical liquid supply method of claim 12, wherein the chemical liquid supply determination process comprises a chemical liquid supply line closure process in which the chemical liquid supply line is closed by using a first valve on the chemical liquid supply line when the impurities are detected.

17. The chemical liquid supply method of claim 16, wherein the chemical liquid supply determination process further comprises a drain line opening process in which the chemical liquid flowing through the chemical liquid supply line is discharged by using a second valve on a drain line.

18. The chemical liquid supply method of claim 17, wherein the chemical liquid supply determination process further comprises a discharge control process in which the drain line is opened on the basis of a set time or a set flow rate.

19. The chemical liquid supply method of claim 12, wherein, in the chemical liquid supply determination process, the impurities detection process is performed again, and a chemical liquid supply line closure process or a discharge control process is performed on the basis of the impurities detection result.

20. A chemical liquid supply unit comprising:
a chemical liquid storage storing IPA as a chemical liquid;
a chemical liquid supply line that is connected to the chemical liquid storage, wherein the chemical liquid flows through the chemical liquid supply line from the chemical liquid storage;
a filter disposed in the chemical liquid supply line;
a drain line connected to the chemical liquid supply line and configured to discharge the chemical liquid flowing through the chemical liquid supply line;
a first valve disposed at a rear end of a connection portion of the drain line where the drain line is connected to the chemical liquid supply line, the first valve being configured to selectively open and close the chemical liquid supply line;
a second valve disposed at the drain line, the second valve being configured to selectively open and close the drain line;
a measurement probe inserted into the chemical liquid supply line, the measurement probe being configured to emit infrared light or near-infrared light to the chemical liquid flowing through the chemical liquid supply line and being configured to detect light transmitted through the chemical liquid or reflected on the chemical liquid;
a Fourier transformer configured to acquire a spectrum from the light detected from the measurement probe;
an analyzer configured to detect an IPA derivative on the basis of the spectrum; and
a controller configured to control the first valve and the second valve on the basis of an analysis result of the analyzer.
